(19) United States
(12) Patent Application Publication
(10) Pub. No.: US 2018/0120400 A1
(43) Pub. Date: May 3, 2018

(54) PROCESSING MRI DATA

(71) Applicant: SHANGHAI NEUSOFT MEDICAL TECHNOLOGY CO., LTD., Shanghai (CN)

(72) Inventors: Haoda DING, Shanghai (CN); Hongyu GUO, Shanghai (CN); Qin XU, Shanghai (CN)

(21) Appl. No.: 15/795,045

(22) Filed: Oct. 26, 2017

(30) Foreign Application Priority Data
Oct. 28, 2016 (CN) 201610963895.8

(51) Int. Cl. G01R 33/56; G01R 33/36; G06T 11/00

(52) U.S. Cl. CPC G01R 33/5608; G01R 33/3621; G06T 2207/10088; G06T 11/003; G01R 33/3607

(57) ABSTRACT

A method of processing Magnetic Resonance Imaging (MRI) data is provided. According to an example of the method, after a set of MRI data of a subject is obtained by an MRI system, interpolation may be performed on real parts and imaginary parts of the set of MRI data, respectively, to obtain real part interpolation results and imaginary part interpolation results. Interpolation is performed on amplitudes of the set of MRI data to obtain amplitude interpolation results. Target interpolation results are determined with the real part interpolation results, the imaginary part interpolation results and the amplitude interpolation results. Then, an MRI image of the subject is reconstructed with the target interpolation results.

### CROSS REFERENCE TO RELATED APPLICATIONS

This application claims priority to Chinese Patent Application No. 201610963895.8, entitled “METHOD AND DEVICE FOR PROCESSING MRI DATA,” filed on Oct. 28, 2016, the entire contents of which are incorporated herein by reference for all purposes.

### BACKGROUND

The present disclosure relates to processing MRI data.

Because of the characteristics of Magnetic Resonance Imaging (MRI), collected MRI data are complex data. For MRI data, complex interpolation is a significant processing step. By performing complex interpolation on MRI data, interpolation results may be obtained and utilized to reconstruct images, thereby obtaining an MRI amplitude image and an MRI phase image.

However, due to the specificity of complex interpolation, performing interpolation on the MRI data with an interpolation method may result in a ripple artifact in the reconstructed MRI amplitude image or phase changes at partial positions in the reconstructed MRI phase image, thereby influencing a doctor's medical diagnosis.

NEUSOFT MEDICAL SYSTEMS CO., LTD. (NMS), founded in 1998 with its world headquarters in China, is a leading supplier of medical equipment, medical IT solutions, and healthcare services. NMS supplies medical equipment with a wide portfolio, including CT, Magnetic Resonance Imaging (MRI), digital X-ray machine, ultrasound, Positron Emission Tomography (PET), Linear Accelerator (LINAC), and biochemistry analyser. Currently, NMS' products are exported to over 60 countries and regions around the globe, serving more than 5,000 renowned customers. NMS's latest successful developments, such as 128 Multi-Slice CT Scanner System, Superconducting MRI, LINAC, and PET products, have led China to become a global high-end medical equipment producer. As an integrated supplier with extensive experience in large medical equipment, NMS has been committed to the study of avoiding secondary potential harm caused by excessive X-ray irradiation to the subject during the CT scanning process.

### BRIEF DESCRIPTION OF DRAWINGS

FIG. 1 is a schematic structure diagram of an MRI system according to an example of the present disclosure.

FIG. 2 is a schematic diagram of an MRI amplitude image with a ripple artifact according to an example of the present disclosure.

FIG. 3 is a schematic diagram of an MRI phase image with phase changes at partial positions according to an example of the present disclosure.

FIG. 4 is a flow diagram of a method of processing MRI data according to an example of the present disclosure.

FIG. 5 is a schematic diagram of an MRI amplitude image obtained according to the method of FIG. 4.

FIG. 6 is a schematic diagram of an MRI phase image obtained according to the method of FIG. 4.

FIG. 7 is a schematic structure diagram of a control apparatus according to an example of the present disclosure.

FIG. 8 is a schematic structure diagram of a device for processing MRI data according to an example of the present disclosure.

### DETAILED DESCRIPTION

The following description is first made to an MRI system and partial terminology in the present disclosure.

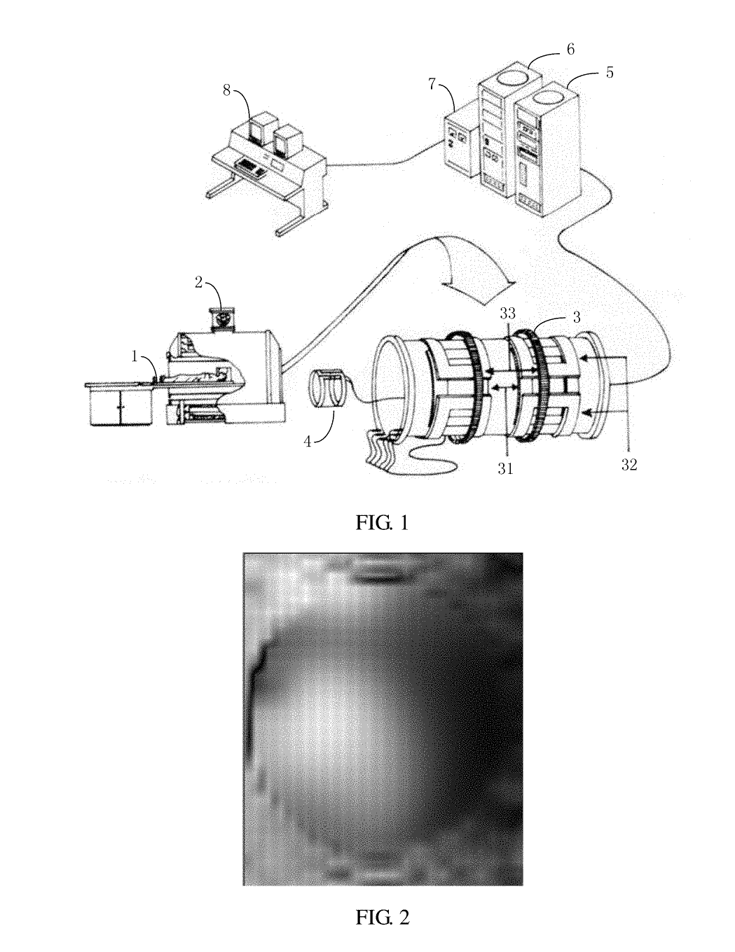

As shown in FIG. 1, it simply illustrates the composition of an MRI system, mainly including an examination bed 1, a magnet 2, gradient coils 3, radio-frequency coils 4, a host computer 5, a gradient amplifier 6, a radio-frequency controller 7 and a console 8, where the gradient coils 3 include an x-direction gradient coil 31, a y-direction gradient coil 32 and a z-direction gradient coil 33.

Complex number: a number in a form of a+bi (both a and b are real numbers) is referred to as a complex number, where a is referred to as a real part, b as an imaginary part and i as an imaginary unit. In addition to the form of a real part plus an imaginary part, a complex number may also be expressed in an exponential form Ae^{iφ}, where A is referred to as an amplitude, φ as a phase, i as an imaginary unit, and e as the base of a natural logarithm, which is also referred to as Euler number and approximately equal to 2.718281828.

Interpolation: it is one of the methods frequently used in data processing. For example, a continuous change of an independent variable x may follow a function ƒ(x), but usually only finite discrete data points may be measured. A method of producing new data points by using existing data points is referred to as interpolation. In image processing, interpolation may increase a resolution of a reconstructed image.

Artifact refers to a part of an image that shows structures or details that a human tissue does not have, which appears due to a particular or some factors during an MRI process. An artifact may lead to image blurring and details loss, and even cause an image to be unrecognizable. The technical solution of the present disclosure will be described below in combination with the accompanying drawings of the description and different examples.

Generally, there are two common complex interpolation methods: one is to perform interpolation on real parts and imaginary parts of complex numbers, respectively, and the other is to perform interpolation on amplitudes and phases of complex numbers, respectively.

However, for MRI data, if interpolation is performed on real parts and imaginary parts of the MRI data, respectively, the interpolation process may be affected by a phase modulation, leading to fluctuation of amplitudes of the MRI data, thereby further resulting in a ripple artifact in a reconstructed MRI amplitude image. Brief description is now made with one-dimensional data. Assuming that t₁=1 and t₂=i, t_{1.5}=0.5+0.5i may be obtained by performing interpolation on t₁ and t₂. From the point of amplitude, |t_{1.5}|=\sqrt{0.5²+0.5²}=0.7071<(|t₁|+|t₂|)/2. It is apparent that the amplitude of t_{1.5} obtained by interpolation and the amplitudes of t₁ and t₂ are nonlinear. Accordingly, a ripple artifact may appear in an MRI amplitude image. As shown in FIG. 2, the white vertical lines are the ripple artifact caused by fluctuation of the amplitude data.

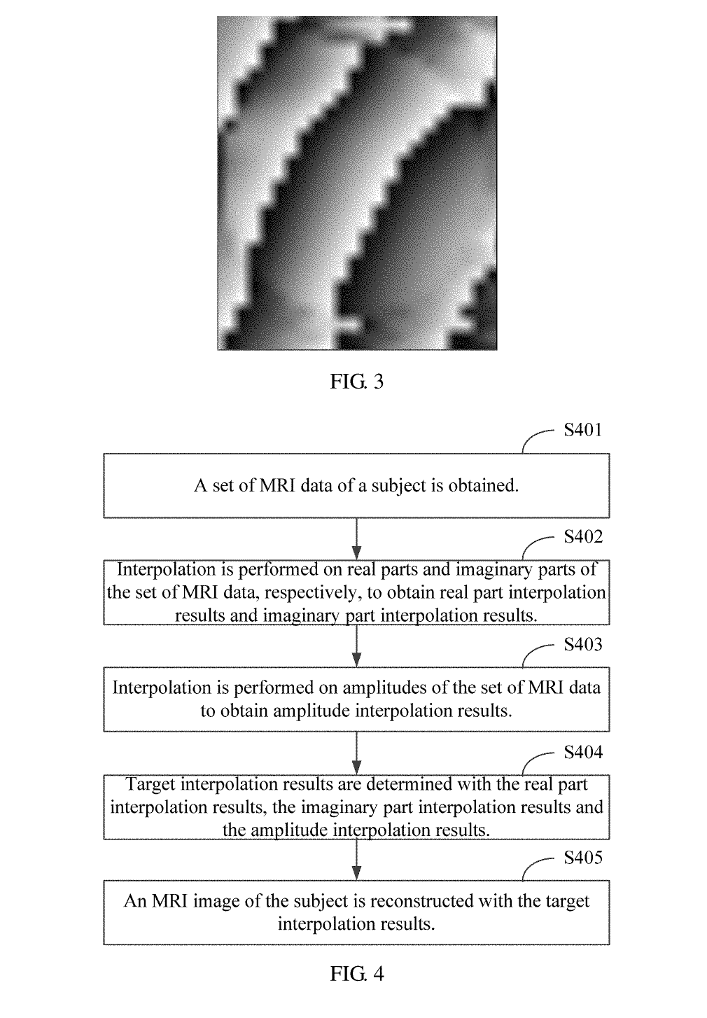

If interpolation is performed on amplitudes and phases of the MRI data, respectively, it may cause phase data to be smoothed, thereby resulting in phase changes at partial positions in a reconstructed MRI phase image, as shown in FIG. 3. In FIG. 3, the boundaries from bright to dark should be smooth curves in theory, but due to inaccurate phase data at partial positions, the boundaries finally present zigzag shapes.

For the problems of a ripple artifact and a phase change caused by performing complex interpolation on MRI data, the currently principal solution is to avoid them by increasing sampling points. To solve the above problems without increasing sampling points, the present disclosure provides a method of processing MRI data. According to the method, interpolation is performed on real parts, imaginary parts and amplitudes of MRI data, respectively, and target interpolation results of the MRI data are determined with three types of interpolation results. The target interpolation results may not only eliminate the ripple effect of the amplitude data but also maintain the accuracy of the phase data.

The method of processing MRI data provided in the present disclosure will be illustrated below. The method may be used in processing not only MRI data but also other complex data. For example, if scanning data collected by Computed Tomography (CT) technology, X ray imaging technology and the like are also complex data in the future, the collected scanning data such as CT data and X ray data may also be processed by using the method.

The method provided in the present disclosure will be illustrated below by taking MRI data for example. FIG. 4 illustrates a flow chart of the method in the present disclosure, which may include the following blocks:

At block 401, a set of MRI data of a subject is obtained.

An MRI datum itself is a complex datum, and may be expressed in the following form:

D(r)=R(r)+i*I(r) (1)

where R(r) and I(r) are a real part and an imaginary part of an MRI datum D(r), respectively, and r=[x,y,z] denotes an image coordinate before interpolation. The MRI data are composed of a finite number of discrete data points.

If expressed in the exponential form, an MRI datum may also be expressed as:

D(r)=M(r).*e^{iϕ(r)}(2)

where M(r) represents an amplitude of an MRI datum D(r), which may be obtained by the following Formula (3); and ϕ(r) represents a phase of the MRI datum, which may be obtained by the following Formula (4).

M(r)={square root over ((R(r)²+I(r)²)}) (3)

ϕ(r)=arctan(I(r)/R(r)) (4)

It is to be noted that “.” herein represents a point operation of discrete data points. For example, “.*” represents multiply operation of points, and “./” represents division operation of points.

At block 402, interpolation is performed on real parts and imaginary parts of the set of MRI data, respectively, to obtain real part interpolation results and imaginary part interpolation results.

In an example, interpolation may be performed on the respective real parts R(r) and imaginary parts I(r) of the set of MRI data, respectively, to obtain the real part interpolation results R′(t):

R′(t)=Inp₁(R(r)) (5)

and imaginary part interpolation results I′(t):

I′(t)=Inp₂(I(r)) (6)

where t=[x′, y′, z′] denotes an MRI image coordinate after interpolation; and r=[x, y, z] denotes the MRI image coordinate before interpolation. It is to be noted that “t” and “r” presented subsequently in the present disclosure have the same meaning as defined herein.

Inp₁ and Inp₂ represent interpolation algorithms, each of which may be one of the existing interpolation algorithms (e.g., linear interpolation, spline interpolation and the like). Inp₁ and Inp₂ may be the same algorithm, and may also be different algorithms.

At block 403, interpolation is performed on amplitudes of the set of MRI data to obtain amplitude interpolation results.

In an example, an amplitude M(r) of each MRI datum D(r) in the MRI data may be calculated first according to the above Formula (3), and then interpolation may be performed on the calculated amplitudes M(r) of the set of MRI data to obtain the amplitude interpolation results M′(t):

M′(t)=Inp₃(M(r)) (7)

where t has the meaning as defined above, representing an MRI image coordinate after interpolation. Inp₃ also represents an interpolation algorithm, which is one of the existing interpolation algorithms, and may be an algorithm that is the same with or different from Inp₁ and Inp₂.

It is to be noted that the value and number of t in R′(t), I′(t) and M′(t) obtained by interpolation are to be consistent no matter which interpolation algorithms Inp₁, Inp₂ and Inp₃ are.

At block 404, target interpolation results are determined with the real part interpolation results, the imaginary part interpolation results and the amplitude interpolation results.

There may be a plurality of methods of calculating the target interpolation results and only the following two methods are exemplified in the present disclosure.

A first method:

Firstly, a new MRI datum D′(t)=R′(t)+i*I′(t) is constructed according to the real part interpolation result R′(t) and the imaginary part interpolation result I′(t) of each MRI datum in the set of MRI data, respectively.

Then, target interpolation results H′(t) are obtained according to the respective amplitude interpolation results M′(t) and each new MRI datum D′(t):

H(t)=M*(t).*D′(t)./|(D′(t))| (8)

Where “| |” represents an operation of calculating an amplitude, i.e.,

|(D′(t))|={square root over ((R′(t)²+I′(t)²))} (8-1).

For Formula (8), M′(t) is equivalent to the amplitude part of H(t), the introduction of which may eliminate the ripple artifact in an MRI image. D′(t)./|(D′(t))| is equivalent to the phase part of H(t), the introduction of which may increase the phase accuracy of the MRI image.

As described above, “.*” and “./” in Formula (8) represent multiply and division operations of points. For example, assuming that M′(t)=5 and D′(t)=1+i when t=[x₁,y₁,z₁], it may be obtained according to Formula (8) that H(t)=(5*(1+i))/\sqrt{2} when t=[x₁,y₁,z₁].

A second method:

Firstly, a new MRI datum D′(t)=R′(t)+i*I′(t) is constructed according to the real part interpolation result R′(t) and the imaginary part interpolation result I′(t) of each MRI datum in the set of MRI data.

Secondly, a phase ϕ′(t) of each new MRI datum D′(t) is calculated:

ϕ′(t)=arctan(I(t)/R′(t)) (9)

Then target interpolation results H(t) are obtained according to the respective amplitude interpolation results M′(t) and the phase ϕ′(t) of each new MRI datum:

H(t)=M′(t).*exp(i.*ϕt)) (10)

For Formula (10), M′(t) is equivalent to the amplitude part of H(t), the introduction of which may eliminate the ripple artifact of an MRI image. exp (i.*ϕ′t)) is equivalent to the phase part of H(t), the introduction of which may increase the phase accuracy of the MRI image.

Substantially, Formula (10) may be regarded as a variation of Formula (8) according to Euler's formula e^{ix}=cos x+isinx. Moreover, H(t) mentioned in the present disclosure may have more logical variations.

At block 405, an MRI image of the subject is reconstructed with the target interpolation results.

For example, image reconstruction may be carried out by directly using the target interpolation results and by a technique well known to a person of ordinary skill in the art to obtain an MRI image. Alternatively, image reconstruction may be carried out with the target interpolation results as well as the original MRI data obtained in the block 401 and by a technique well known to a person of ordinary skill in the art to obtain an MRI image, which will not be redundantly described herein.

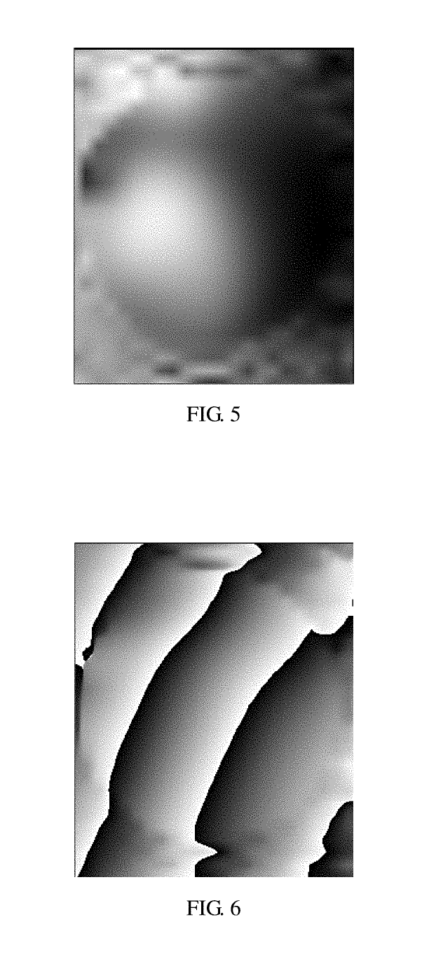

To verify the applicability of the method of processing MRI data provided in the present disclosure, experimental verification is also performed according to the present disclosure. FIG. 5 shows an MRI amplitude image reconstructed by the method provided in the present disclosure, and FIG. 6 shows an MRI phase image reconstructed by the method provided in the present disclosure. By comparing FIG. 2 with FIG. 5, it may be seen that the method provided in the present disclosure may eliminate the ripple effect of amplitude data. By comparing FIG. 3 with FIG. 6, it may be seen that the method provided in the present disclosure may increase the accuracy of phase data and has good applicability.

The foregoing description is made to the method provided in the present disclosure. The following description will be made to an apparatus provided in the present disclosure.

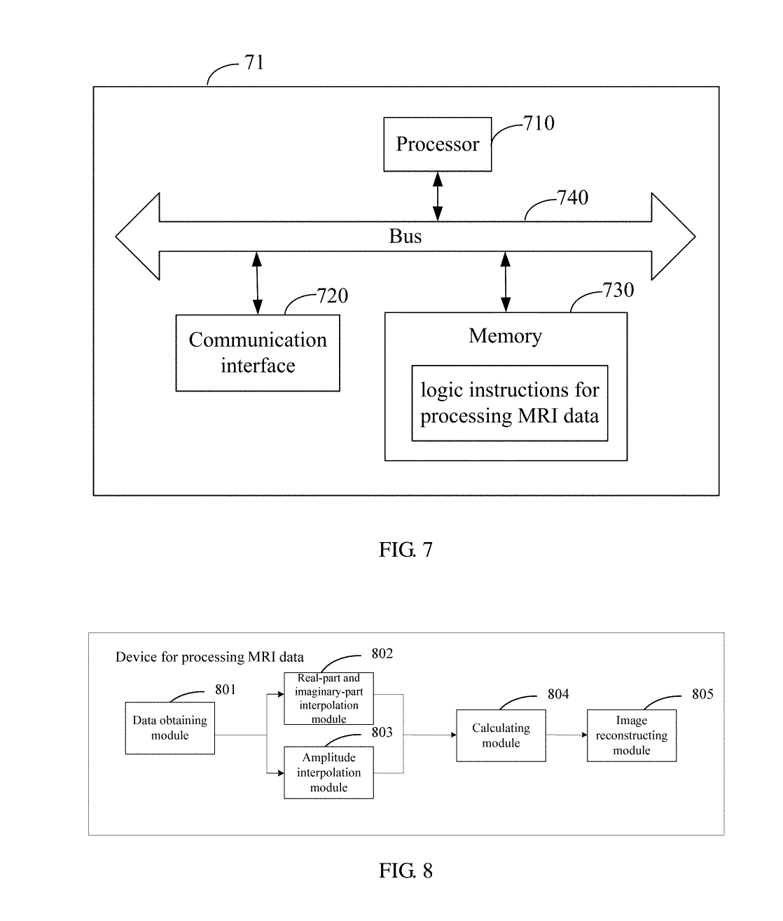

The method of processing MRI data provided in the present disclosure is used in data processing after the data are collected by scanning, and may be executed by, but not limited to, a data processing software installed in a computer system. As shown in FIG. 7, the method provided in the present disclosure may be executed by a control apparatus 71. The control apparatus 71 may include a processor 710, a communication interface 720, a memory 730 and a bus 740. The processor 710, the communication interface 720 and the memory 730 communicate with one another via the bus 740.

The memory 730 may store logic instructions for processing MRI data. The memory may be, for example, a non-volatile memory. The processor 710 may invoke and execute the logic instructions for processing MRI data in the memory 730 to carry out the above-described method of processing MRI data.

If the functions of the logic instructions for processing MRI data are implemented in the form of software function units and sold or used as an independent product, the logic instructions may be stored in a computer-readable storage medium. Based on such an understanding, part of the technical solutions of the present disclosure may be embodied in the form of a software product, and the computer software product may be stored in a storage medium and include a plurality of instructions for causing a computer device (which may be a personal computer, a server or a network device) to execute all or part of blocks of the method described in different examples of the present disclosure. The above-mentioned storage medium includes: all kinds of media capable of storing program codes such as a USB disk, a mobile hard disk, a Read-Only Memory (ROM), a Random Access Memory (RAM), a magnetic disk or a compact disk.

The above-mentioned logic instructions for processing MRI data may be referred to as a “device for processing MRI data” to be used in an MRI system. The device may be divided into different functional modules. As shown in FIG. 8, the device may include: a data obtaining module 801, a real-part and imaginary-part interpolating module 802, an amplitude interpolating module 803, a calculating module 804, and an image reconstructing module 805.

The data obtaining module 801 is configured to obtain a set of MRI data of a subject.

The real-part and imaginary-part interpolating module 802 is configured to perform interpolation on real parts and imaginary parts of the set of MRI data, respectively, to obtain real part interpolation results and imaginary part interpolation results.

The amplitude interpolating module 803 is configured to perform interpolation on amplitudes of the set of MRI data to obtain amplitude interpolation results.

The calculating module 804 is configured to determine target interpolation results with the real part interpolation results, the imaginary part interpolation results and the amplitude interpolation results.

The image reconstructing module 805 is configured to reconstruct an MRI image of the subject with the target interpolation results.

Alternatively, the real-part and imaginary-part interpolating module 802 is specifically configured to:

determine a real part of an MRI datum D(r)=R(r)+i*I(r) in the set of MRI data as R(r) and an imaginary part of the MRI datum as I(r);
perform interpolation on the respective real parts R(r) and imaginary parts I(r) of the set of MRI datum D(r), respectively, to obtain real part interpolation results R′(t) and imaginary part interpolation results I′(t),
where r represents an image coordinate [x, y, z] before interpolation, and t represents the image coordinate [x′, y′, z′] after interpolation.

Alternatively, in an implementation, the amplitude interpolating module 803 is specifically configured to:

calculate an amplitude M(r)={square root over ((R(r)²+I(r)²))} of each MRI datum D(r)=R(r)+i*I(r) of the set of MRI data;
perform interpolation on the respective amplitudes M(r) of the set of MRI data to obtain the amplitude interpolation results M′(t),
where r represents an image coordinate [x, y, z] before interpolation, and t represents the image coordinate [x′, y′, z′] after interpolation.

Alternatively, the calculating module 804 is specifically configured to:

construct a new MRI datum D′(t)=R′(t)+i*I′(t) according to the real part interpolation result R′(t) and the imaginary part interpolation result I′(t) of each MRI datum in the set of MRI data, and
obtain target interpolation results H(t)=M′(t).*D′(t)./|)D′(t))| according to the respective amplitude interpolation results M′(t) and each new MRI datum D′(t),
where |(D′(t))|={square root over ((R′(t)²+I′(t)²))}, and t represents an image coordinate [x′, y′, z′] after interpolation.

Alternatively, in another implementation, the calculating module 804 is specifically configured to:

construct a new MRI datum D′(t)=R′(t)+i*I′(t) according to the real part interpolation result R′(t) and the imaginary part interpolation result I′(t) of each MRI datum in the set of MRI data;
calculate a phase ϕ′(t)=arctan(I′(t)/R′(t)) of each new MRI datum D′(t); and
obtain target interpolation results H(t)=M′(t).*exp(i.*ϕ′(t)) according to the respective amplitude interpolation results M′(t) and the phase ϕ′(t) of each new MRI datum,
where t represents an image coordinate [x′, y′, z′] after interpolation.

Since the apparatus embodiments substantially correspond to the method embodiments, a reference may be made to part of the descriptions of the method embodiments for the related part. The apparatus embodiments described above are merely illustrative, where the units described as separate members may be or not be physically separated, and the members displayed as units may be or not be physical units, i.e., may be located in one place, or may be distributed to a plurality of network units. Part or all of the modules may be selected according to actual requirements to implement the objectives of the solutions in the embodiments. Those of ordinary skill in the art may understand and carry out them without creative work.

The foregoing disclosure is merely illustrative of the preferred embodiments of the disclosure but not intended to limit the disclosure, and any modifications, equivalent substitutions, adaptations thereof made without departing from the spirit and scope of the disclosure shall be encompassed in the claimed scope of the appended claims.

1. A method of processing Magnetic Resonance Imaging (MRI) data, comprising:
obtaining, by an MRI system, a set of MRI data of a subject;
performing, by the MRI system, interpolation on real parts and imaginary parts of the set of MRI data, respectively, to obtain real part interpolation results and imaginary part interpolation results;
performing, by the MRI system, interpolation on amplitudes of the set of MRI data to obtain amplitude interpolation results;
determining, by the MRI system, target interpolation results with the real part interpolation results, the imaginary part interpolation results, and the amplitude interpolation results; and
reconstructing, by the MRI system, an MRI image of the subject with the target interpolation results.

2. The method according to claim 1, wherein performing interpolation on the real parts and the imaginary parts of the set of MRI data, respectively, comprises:
determining, by the MRI system, a real part of each MRI datum D(r)=R(r)+i*I(r) in the set of MRI data as R(r) and an imaginary part of the MRI datum as I(r);
performing, by the MRI system, interpolation on the respective real parts R(r) of the set of MRI data to obtain the real part interpolation results R′(t); and
performing, by the MRI system, interpolation on the respective imaginary parts I(r) of the set of MRI data to obtain the imaginary part interpolation results I′(t),
wherein r represents an image coordinate [x, y, z] before interpolation, and t represents the image coordinate [x′, y′, z′] after interpolation.

3. The method according to claim 2, wherein performing interpolation on the amplitudes of the set of MRI data comprises:
calculating, by the MRI system, an amplitude M(r)={square root over ((R(r)²+I(r)²))} of each MRI datum D(r)=R(r)+i*I(r) of the set of MRI data; and
performing, by the MRI system, interpolation on the respective amplitudes M(r) of the set of MRI data to obtain the amplitude interpolation results M′(t),
wherein r represents an image coordinate [x, y, z] before interpolation, and t represents the image coordinate [x′, y′, z′] after interpolation.

4. The method according to claim 3, wherein determining the target interpolation results with the real part interpolation results, the imaginary part interpolation results, and the amplitude interpolation results comprises:
constructing, by the MRI system, a new MRI datum D′(t)=R′(t)+i*I′(t) according to the real part interpolation result R′(t) and the imaginary part interpolation result I′(t) of each MRI datum in the set of MRI data; and
obtaining, by the MRI system, the target interpolation results H(t)=M′(t).*D′(t)./|(D′(t))| according to the respective amplitude interpolation results M′(t) and each new MRI datum D′(t),
wherein |(D′(t))|={square root over ((R′(t)²+I′(t)²))}, and t represents an image coordinate [x′, y′, z′] after interpolation.

5. The method according to claim 3, wherein determining the target interpolation results with the real part interpolation results, the imaginary part interpolation results and the amplitude interpolation results comprises:
constructing, by the MRI system, a new MRI datum D′(t)=R′(t)+i*I′(t) according to the real part interpolation result R′(t) and the imaginary part interpolation result I′(t) of each MRI datum in the set of MRI data;
calculating, by the MRI system, a phase ϕ′(t)=arctan(I′(t)/R′(t)) of each new MRI datum D′(t); and
obtaining, by the MRI system, the target interpolation results H(t)=M′(t).*exp(i.*ϕ′(t)) according to the respective amplitude interpolation results M′(t) and the phase ϕ′(t) of each new MRI datum,
wherein t represents an image coordinate [x′, y′, z′] after interpolation.

6. An apparatus for processing Magnetic Resonance Imaging (MRI) data used in an MRI system, comprising:
a processor; and
a machine-readable storage medium for storing machine-executable instructions executable by the processor and corresponding to a control logic for processing MRI data,
wherein by executing the machine-executable instructions, the processor is caused to:
obtain a set of MRI data of a subject;
perform interpolation on real parts and imaginary parts of the set of MRI data, respectively, to obtain real part interpolation results and imaginary part interpolation results;
perform interpolation on amplitudes of the set of MRI data to obtain amplitude interpolation results;
determine target interpolation results with the real part interpolation results, the imaginary part interpolation results, and the amplitude interpolation results; and
reconstruct an MRI image of the subject with the target interpolation results.

7. The apparatus according to claim 6, wherein when performing interpolation on the real parts and the imaginary parts of the set of MRI data, respectively, to obtain the real part interpolation results and the imaginary part interpolation results, the machine-executable instructions cause the processor to:
determine a real part of each MRI datum D(r)=R(r)+i*I(r) in the set of MRI data as R(r) and an imaginary part of the MRI datum as I(r);
perform interpolation on the respective real parts R(r) and the imaginary parts I(r) of the set of the MRI data to obtain the real part interpolation results R′(t) and the imaginary part interpolation results I′(t),
wherein r represents an image coordinate [x, y, z] before interpolation, and t represents the image coordinates [x′, y′, z′] after interpolation.

8. The apparatus according to claim 7, wherein when performing interpolation on the amplitudes of the set of MRI data to obtain the amplitude interpolation results, the machine-executable instructions cause the processor to:
calculate an amplitude M(r)={square root over ((R(r)²+I(r)²))} of each MRI datum D(r)=R(r)+i*I(r) of the set of MRI data; and
perform interpolation on the respective amplitudes M(r) of the set of MRI data to obtain the amplitude interpolation results M′(t),
wherein r represents an image coordinate [x, y, z] before interpolation, and t represents the image coordinate [x′, y′, z′] after interpolation.

9. The apparatus according to claim 8, wherein determining the target interpolation results with the real part interpolation results, the imaginary part interpolation results, and the amplitude interpolation results, the machine-executable instructions cause the processor to:
construct a new MRI datum D′(t)=R′(t)+i*I′(t) according to the real part interpolation result R′(t) and the imaginary part interpolation result I′(t) of each MRI datum in the set of MRI data; and
obtain the target interpolation results H(t)=M′(t).*D′(t)./|(D′(t))| according to the respective amplitude interpolation results M′(t) and each new MRI datum D′(t),
wherein |(D′(t))|={square root over ((R′(t)²+I′(t)²))}, and t represents an image coordinate [x′, y′, z′] after interpolation.

10. The apparatus according to claim 8, wherein determining the target interpolation results with the real part interpolation results, the imaginary part interpolation results, and the amplitude interpolation results, the machine executable instructions cause the processor to:
construct a new MRI datum D′(t)=R′(t)+i*I′(t) according to the real part interpolation result R′(t) and the imaginary part interpolation result I′(t) of each MRI datum in the set of MRI data;
calculate a phase ϕ′(t)=arctan(I′(t)/R′(t)) of each new MRI datum D′(t); and
obtain the target interpolation results H(t)=M′(t).*exp(i.*ϕ′(t)) according to the respective amplitude interpolation results M′(t) and the phase ϕ′(t) of each new MRI datum,
wherein t represents an image coordinate [x′, y′, z′] after interpolation.

11. A machine-readable storage medium that stores machine-executable instructions executed by one or more processors, wherein the machine-executable instructions cause the processor to execute a method of processing MRI data, and the method comprises:
obtaining a set of MRI data of a subject;
performing interpolation on real parts and imaginary parts of the set of MRI data, respectively, to obtain real part interpolation results and imaginary part interpolation results;
performing interpolation on amplitudes of the set of MRI data to obtain amplitude interpolation results;
determining target interpolation results with the real part interpolation results, the imaginary part interpolation results and the amplitude interpolation results; and
reconstructing an MRI image of the subject with the target interpolation results.
